(19) United States
(12) Patent Application Publication
(10) Pub. No.: US 2008/0170451 A1
(43) Pub. Date: Jul. 17, 2008

(54) METHOD AND CIRCUIT FOR SETTING TEST MODE OF SEMICONDUCTOR MEMORY DEVICE

(76) Inventor: Yong-gyu Chu, Seoul (KR)

Correspondence Address: F. CHAU & ASSOCIATES, LLC, 130 WOODBURY ROAD, WOODBURY, NY, 11797, US

(21) Appl. No.: 11/971,606

(22) Filed: Jan. 9, 2008

(30) Foreign Application Priority Data
Jan. 11, 2007 (KR) 10-2007-0003392

(51) Int. Cl. G11C 29/00

(52) U.S. Cl. 365/201

(57) ABSTRACT

A test mode setting method and circuit that reduce the number of signal lines, thereby minimizing the number of wires of a semiconductor memory device. The method includes: sequentially activating a plurality of selection signals; when each selection signal is activated, activating one of a plurality of test mode addresses corresponding to the activated selection signal; when the last one of the selection signals is activated, and one of the test mode addresses corresponding to the last selection signal is activated, activating a test mode corresponding to the activated test mode address.

### BACKGROUND OF THE INVENTION

This application claims the priority of Korean Patent Application No. 10-2007-0003392, filed on Jan. 11, 2007, in the Korean Intellectual Property Office, the disclosure of which is incorporated herein in its entirety by reference.

1. Technical Field

The present disclosure relates to a semiconductor memory device and, more particularly, to a method and circuit for setting a test mode of a semiconductor memory device.

2. Discussion of Related Art

Semiconductor memory devices have functions called a mode register set (MRS) and an extended mode register set (EMRS) that are used to set a general operation mode. Semiconductor memory devices also have a function called a test mode register set (TMRS) to efficiently proceed with a test operation. An example of a test mode used in semiconductor memory devices is disclosed in U.S. Pat. No. 6,269,038 B1.

Semiconductor memory devices need various types of test modes in order to increase test efficiency. The more complicated operations semiconductor memory devices perform, the more test modes semiconductor memory devices require. In order to selectively activate these test modes, semiconductor memory devices need many signal lines, which increases the number of wires of the semiconductor memory devices, ending in an increase of chip size.

FIG. 1 is a timing diagram of a conventional test mode setting method. FIG. 2 is a circuit diagram of a test mode setting circuit according to the conventional test mode setting method whose timing diagram is illustrated in FIG. 1.

A predetermined test mode is activated through the use of three steps called CATEGORY, SUB-CATEGORY, and ITEM. The number of steps can be less or more than three according to the number of test modes required.

For example, if the number of control signals CAT corresponding to the first step CATEGORY is k, the number of control signals SCAT corresponding to the second step SUB-CATEGORY is m, and the number of control signals ITEM corresponding to the third step ITEM is n, then k×m×n types of test modes can be selectively activated. Therefore, k+m+n signal lines are required to transfer the control signals CAT, SCAT, and ITEM. Referring to FIGS. 1 and 2, the control signals CAT corresponding to the first step CATEGORY, the control signals SCAT corresponding to the second step SUB-CATEGORY, and the control signals ITEM corresponding to the third step ITEM each number eight.

In more detail, if a command is input to select CATEGORY 2 at a first step, a control signal CAT<2> among the eight control signals CAT<0-7> is activated as logic high. If a command is input to select SUB-CATEGORY 5 at a second step, a control signal SCAT<5> among the eight control signals SCAT<0-7> is activated as logic high. If a command is input to select ITEM 1 at a third step, a control signal ITEM<L> among the eight control signals ITEM<0-7> is activated as logic high.

Therefore, an AND gate 21 outputs a logic high, so that an output signal TESTMODE 2, 5, 1 of a flipflop 23 becomes logic high, which in this example is a power voltage VDD level. In that case, a test mode corresponding to the output signal TESTMODE 2, 5, 1 is completely set.

Similarly, if a command is input to select CATEGORY 4 at a first step, a control signal CAT<4> is activated as logic high. If a command is input to select SUB-CATEGORY 1 at a second step, a control signal SCAT<1> is activated as logic high. If a command is input to select ITEM 7 at a third step, a control signal ITEM<7> is activated as logic high.

Therefore, an AND gate 25 outputs logic high so that an output signal TESTMODE 4, 1, 7 of a flipflop 27 becomes logic high. In that case, a test mode corresponding to the output signal TESTMODE 4, 1, 7 is completely set.

The conventional test mode setting method and circuit, however, need many signal lines to transfer the control signals CAT, SCAT, ITEM, which increases the number of wires of a semiconductor memory device, thereby causing an increase in chip size.

### SUMMARY OF THE INVENTION

Exemplary embodiments of the present invention provide a test mode setting method that reduces the number of signal lines, thereby minimizing the number of wires of a semiconductor memory device.

An exemplary embodiment of the present invention also provides a test mode setting circuit that reduces the number of signal lines, thereby minimizing the number of wires of a semiconductor memory device.

According to an exemplary embodiment of the present invention, there is provided a test mode setting method in a semiconductor memory device including a plurality of test modes, the method comprising: sequentially activating a plurality of selection signals; when each selection signal is activated, activating one of a plurality of test mode addresses corresponding to the activated selection signal; when the last one of the selection signals is activated, and one of the test mode addresses corresponding to the last selection signal is activated, activating a test mode corresponding to the activated test mode address.

According to an exemplary embodiment of the present invention, there is provided a test mode setting circuit of a semiconductor memory device including a plurality of test modes, the circuit comprising: a first flipflop receiving a corresponding test mode address among a plurality of test mode addresses as a data input, and receiving a first activated selection signal among a plurality of sequentially activated selection signals as a clock input; and a second flipflop receiving a result obtained by AND operating an output of the first flipflop and the corresponding test mode address as the data input, and receiving a second activated selection signal as the clock input.

When there are two selection signals, an output of the second flip-flop corresponds to a control signal of a test mode that is to be activated, and if the control signal is activated, the test mode is activated.

According to an exemplary embodiment of the present invention, there is provided a test mode setting circuit of a semiconductor memory device including a plurality of test modes, the circuit comprising: a first flipflop receiving a corresponding test mode address from among a plurality of test mode addresses as a data input, and receiving a first activated selection signal from among a plurality of sequentially activated selection signals as a clock input; a second flipflop receiving a result obtained by AND operating an output of the first flipflop and the corresponding test mode address as the data input, and receiving a second activated selection signal as the clock input; and a third flipflop receiving a result obtained by AND operating an output of the second flipflop and the corresponding test mode address as the data input, and receiving a third activated selection signal as the clock input

When there are three selection signals, an output of the third flipflop corresponds to a control signal of a test mode that is to be activated.

If the control signal is activated, the test mode is activated.

### BRIEF DESCRIPTION OF THE DRAWINGS

Exemplary embodiments of the present invention will be understood in more detail from the following descriptions taken in conjunction with the attached drawings, in which:

FIG. 1 is a timing diagram of a conventional test mode setting method;

FIG. 2 is a circuit diagram of a test mode setting circuit according to the conventional test mode setting method having the timing diagram illustrated in FIG. 1;

FIG. 3 is a timing diagram of a test mode setting method according to an exemplary embodiment of the present invention;

FIG. 4 is a circuit diagram of a test mode setting circuit according to an exemplary embodiment of the present invention using the test mode setting method having the timing diagram illustrated in FIG. 3; and

FIG. 5 is a circuit diagram of a test mode setting circuit according to an exemplary embodiment of the present invention using the test mode setting method having the timing diagram illustrated in FIG. 3.

### DETAILED DESCRIPTION OF EXEMPLARY EMBODIMENTS

The present invention will now be described more fully with reference to the accompanying drawings, in which exemplary embodiments of the invention are shown. The invention may, however, be embodied in many different forms and should not be construed as being limited to the exemplary embodiments set forth therein; rather, these exemplary embodiments are provided so that this disclosure will be thorough and complete, and will fully convey the concept of the invention to those of ordinary skill in the art. Like reference numerals in the drawings denote like elements, and thus their description will be omitted.

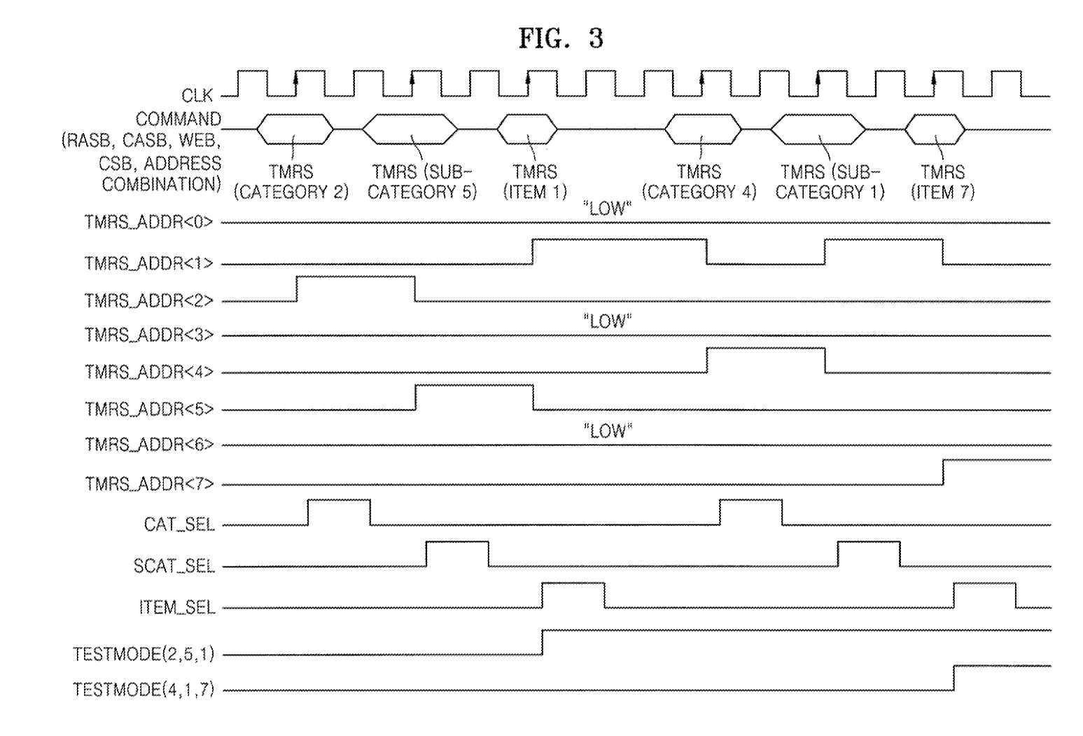

FIG. 3 is a timing diagram of a test mode setting method according to an exemplary embodiment of the present invention. A predetermined test mode is activated through a first step CATEGORY, a second step SUB-CATEGORY, and a third step ITEM. The number of steps can be less or more than three according to the number of test modes required.

Referring to FIG. 3, the test mode setting method of the present exemplary embodiment uses three selection signals CAT_SEL, SCAT_SEL, and ITEM_SEL and eight test mode addresses TMRS_ADDR<0-7>.

The selection signal CAT_SEL selects a first step CATEGORY, the selection signal SCAT_SEL selects a second step SUB_CATEGORY, and the selection signal ITEM_SEL selects a third step ITEM. The test mode addresses TMRS_ADDR<0-7> are used to notify which category the first step CATEGORY selects, which sub-category the second step SUB_CATEGORY selects, and which item the third step ITEM selects.

The three selection signals CAT_SEL, SCAT_SEL, and ITEM_SEL are sequentially activated. One of the eight test mode addresses TMRS_ADDR<0-7> corresponding to each selection signal is simultaneously activated. When the final selection signal ITEM_SEL is activated, and one of the eight test mode addresses TMRS_ADDR<0-7> corresponding to the selection signal ITEM_SEL is activated, a test mode corresponding to the activated test mode address is activated.

In more detail, if a command is input to select category 2 at the first step, the first selection signal CAT_SEL is activated as logic high, and the test mode address TMRS_ADDR<2> is activated as logic high. If a command is input to select sub-category 5 at the second step, the second selection signal SCAT_SEL is activated as logic high, and the test mode address TMRS_ADDR<5> is activated as logic high. If a command is input to select item 1 at the third step, the final selection signal ITEM_SEL is activated as logic high, and the test mode address TMRS_ADDR<1> is activated as logic high.

Therefore, the test mode control signal TESTMODE 2, 5, 1 becomes logic high, and thus a test mode accordingly is set.

On the other hand, if a command is input to select category 4 at the first step, the first selection signal CAT_SEL is activated as logic high, and the test mode address TMRS_ADDR<4> is activated as logic high. If a command is input to select sub-category 1 at the second step, the second selection signal SCAT_SEL is activated as logic high, and the test mode address TMRS_ADDR<1> is activated as logic high. If a command is input to select item 7 at the third step, the final selection signal ITEM_SEL is activated as logic high, and the test mode address TMRS_ADDR<7> is activated as logic high.

Therefore, the test mode control signal TESTMODE 4, 1, 7 becomes logic high, and thus a test mode corresponding to the test mode control signal TESTMODE 4, 1, 7 is set.

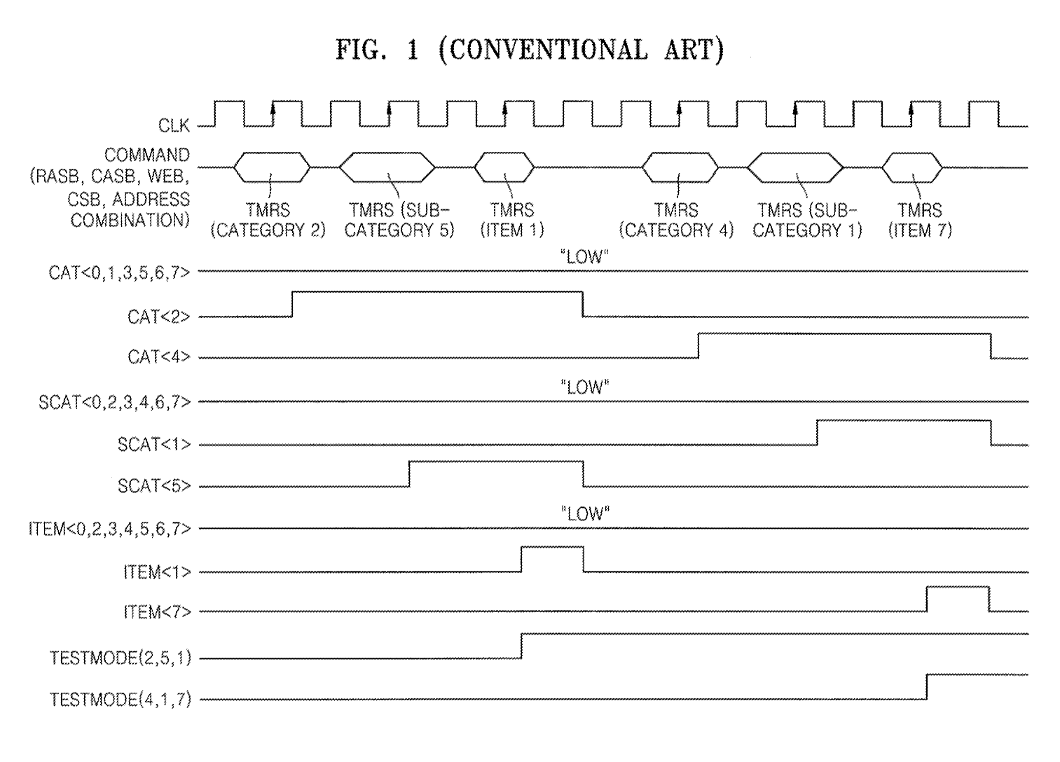

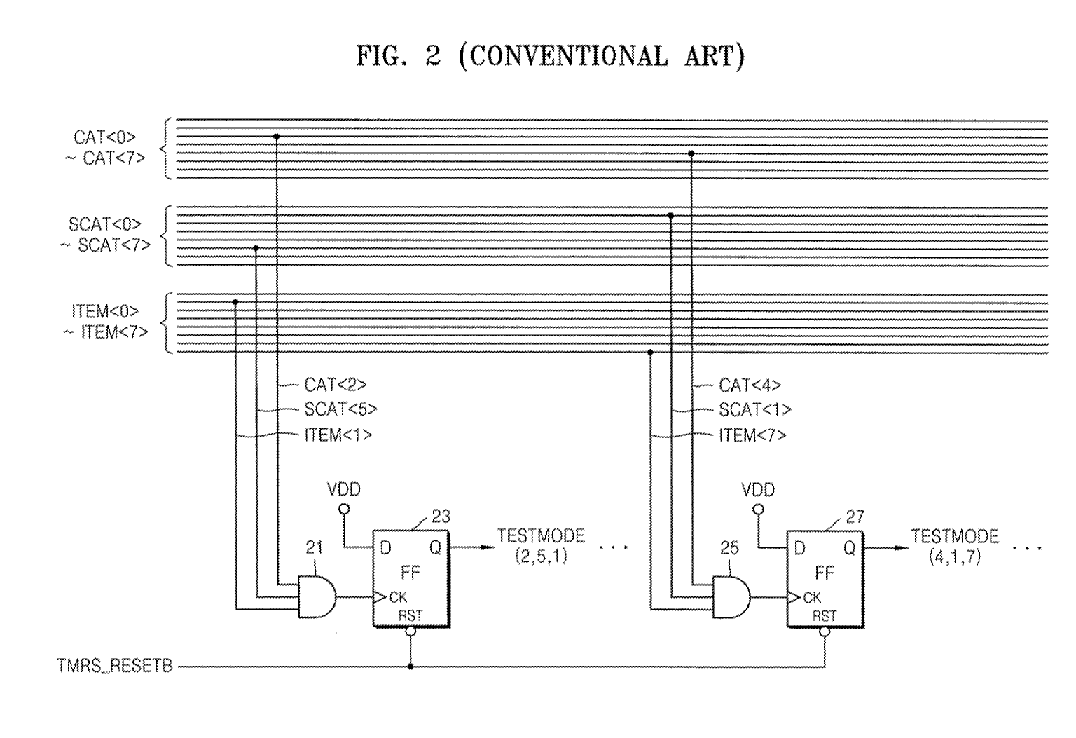

When a circuit is realized according to the test mode setting method of the present exemplary embodiment, x+3 (x denotes the maximum number among k, m, and n described with reference to FIG. 2) signal lines are needed. If there are 8 each of the k+m+n signal lines, as described in FIGS. 1 and 2, when a circuit is realized according to the conventional test mode setting method, 24 signal lines are needed, whereas when the circuit is realized according to the test mode setting method of the present exemplary embodiment, only 11 signal lines are needed. The test mode setting method of the present exemplary embodiment dramatically reduces the number of lines, thereby greatly reducing the number of wires of a semiconductor memory device.

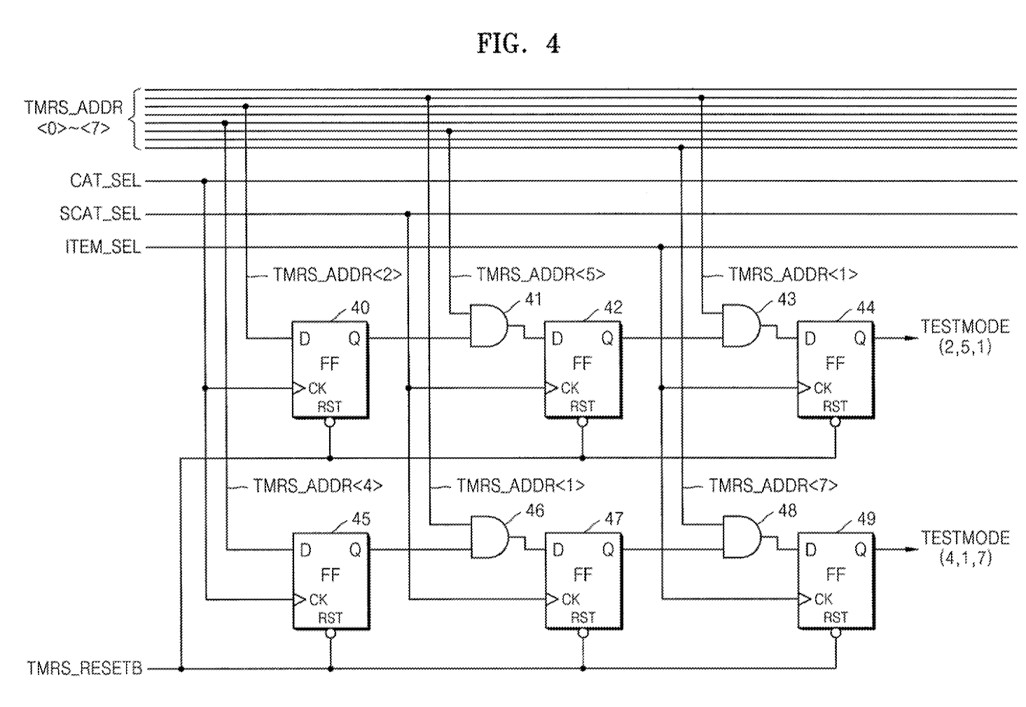

FIG. 4 is a circuit diagram of a test mode setting circuit using the test mode setting method having the timing diagram illustrated in FIG. 3 according to an exemplary embodiment of the present invention. Referring to FIG. 4, the test mode setting circuit of the present exemplary embodiment includes three selection signals CAT_SEL, SCAT_SEL, and ITEM_SEL, eight test mode addresses TMRS_ADDR<0-7>, flip-flops 40, 42, 44, 45, 47, and 49, and AND gates 41, 43, 46, and 48.

The three flipflops 40, 42, and 44 and two AND gates 41 and 43 operate in order to set a test mode corresponding to a test mode control signal TESTMODE 2, 5, 1. The first flipflop 40 receives the test mode address TMRS_ADDR<2> as a data input D, and receives the first selection signal CAT_SEL as a clock input CK. The second flipflop 42 receives an output of the first flipflop 40 and a result obtained by AND operating the test mode address TMRS_ADDR<5> by the AND gate 41 as the data input D, and receives the second selection signal SCAT_SEL as the clock input CK.

The third flipflop 44 receives an output of the second flipflop 42 and a result obtained by AND operating the test mode address TMRS_ADDR<1> by the AND gate 43 as the data input D, and receives the third selection signal ITEM_SEL as the clock input CK.

The three flipflops 45, 47, and 49 and two AND gates 46 and 48 operate in order to set a test mode corresponding to a test mode control signal TESTMODE 4, 1, 7. The first flipflop 45 receives the test mode address TMRS_ADDR<4> as the data input D, and receives the first selection signal CAT_SEL as the clock input CK. The second flipflop 47 receives an output of the first flipflop 45 and a result obtained by AND operating the test mode address TMRS_ADDR<4> by the AND gate 46 as the data input D, and receives the second selection signal SCAT_SEL as the clock input CK.

The third flipflop 49 receives an output of the second flipflop 47 and a result obtained by AND operating the test mode address TMRS_ADDR<7> by the AND gate 48 as the data input D, and receives the third selection signal ITEM_SEL as the clock input CK. When an output of the third flipflop 49, that is, the test mode control signal TESTMODE 4, 1, 7, becomes logic high, a test mode corresponding to the test mode control signal TESTMODE 4, 1, 7 is set.

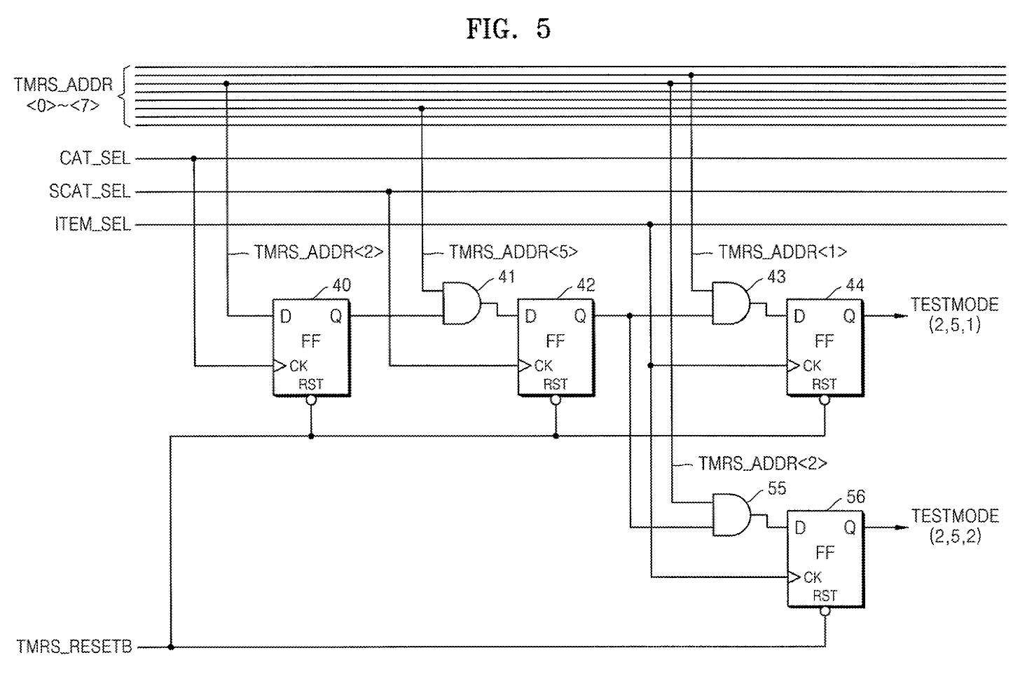

FIG. 5 is a circuit diagram of a test mode setting circuit according to an exemplary embodiment of the present invention using the test mode setting method having the timing diagram illustrated in FIG. 3. Referring to FIG. 5, when several test modes belong to the same category and sub-category, a flipflop operated by the selection signal CAT_SEL and a flipflop operated by the selection signal SCAT_SEL are shared in order to reduce the number of required flip-flops.

For example, test mode control signals TESTMODE 2, 5, 1 and TESTMODE 2, 5, 2 for setting test modes that belong to the same category 2 and sub-category 5 share flopflops 40 and 42 and an AND gate 41. The test mode control signal TESTMODE 2, 5, 2 further uses a flipflop 56 that receives an output of AND gate 55 that receives an output of the flipflop 42 and the test mode address TMRS_ADDR<2>, and an output of the AND gate 55 as a data input D, and receives the selection signal ITEM_SEL as a clock input CK.

Therefore, when several test modes belong to the same category and sub-category, test mode control signals can share flipflops, thereby reducing flip-flops required.

The test mode setting method and circuit according to exemplary embodiments of the present invention dramatically reduce the number of signal lines, thereby greatly reducing the number of wires of a semiconductor memory device.

While the present invention has been particularly shown and described with reference to exemplary embodiments thereof, it will be understood by those of ordinary skill in the art that various changes in form and details may be made therein without departing from the spirit and scope of the present invention, as defined by the following claims.

What is claimed is:

1. A test mode setting method in a semiconductor memory device including a plurality of test modes, the method comprising:
sequentially activating a plurality of selection signals;
when each selection signal is activated, activating one of a plurality of test mode addresses corresponding to the activated selection signal; and
when a last one of the plurality of selection signals is activated, and one of the test mode addresses corresponding to the last one of the plurality of selection signals is activated, activating a test mode corresponding to the activated test mode address.

2. A test mode setting circuit of a semiconductor memory device including a plurality of test modes, the circuit comprising:
a first flipflop receiving a corresponding test mode address from among a plurality of test mode addresses as a data input, and receiving a first activated selection signal from among a plurality of sequentially activated selection signals as a clock input; and
a second flipflop receiving a result obtained by AND operating an output of the first flipflop and the corresponding test mode address as the data input, and receiving a second activated selection signal as the clock input.

3. The circuit of claim 2, wherein when there are two selection signals, an output of the second flipflop corresponds to a control signal of a test mode that is to be activated.

4. The circuit of claim 3, wherein when the control signal is activated, the test mode is activated.

5. A test mode setting circuit of a semiconductor memory device including a plurality of test modes, the circuit comprising:
a first flipflop receiving a corresponding test mode address from among a plurality of test mode addresses as a data input, and receiving a first activated selection signal from among a plurality of sequentially activated selection signals as a clock input;
a second flipflop receiving a result obtained by AND operating an output of the first flipflop and the corresponding test mode address as the data input, and receiving a second activated selection signal as the clock input; and
a third flipflop receiving a result obtained by AND operating an output of the second flipflop and the corresponding test mode address as the data input, and receiving a third activated selection signal as the clock input

6. The circuit of claim 5, wherein when there are three selection signals, an output of the third flipflop corresponds to a control signal of a test mode that is to be activated.

7. The circuit of claim 6, wherein when the control signal is activated, the test mode is activated.
